(19) United States
(12) Patent Application Publication
(10) Pub. No.: US 2026/0322401 A1
(43) Pub. Date: Oct. 15, 2026

(54) CYCLIC REDUNDANCY CHECK CONFIGURATION IN TRANSPORT BLOCK

(71) Applicant: Lenovo (United States) Inc., Morrisville, NC (US)

(72) Inventors: Alexander Golitschek Edler von Elbwart, Darmstadt (DE); Joachim Löhr, Wiesbaden (DE)

(73) Assignee: Lenovo (United States) Inc., Morrisville, NC (US)

(21) Appl. No.: 19/179,674

(22) Filed: Apr. 15, 2025

(51) Int. Cl. H03M 13/09; H04L 1/00; H04W 72/231

(52) U.S. Cl. CPC H03M 13/091; H04L 1/0003; H04W 72/231

(57) ABSTRACT

Various aspects of the present disclosure relate to cyclic redundancy check (CRC) configuration in transport block (TB). A user equipment (UE) may obtain data for transmission, the data formable into a TB of the data, the TB includes code block groups (CBGs), and each CBG includes one or more code blocks (CBs) that each include a subset of the data, where the CBGs are associated with modulation and coding scheme (MCS) levels of a plurality of MCSs. The UE may transmit a CRC, where the CRC is calculated for the data or a subset of the data in the TB using an MCS level associated with at least one of the CBGs or CBs.

### TECHNICAL FIELD

The present disclosure relates to wireless communications, and more specifically to cyclic redundancy check (CRC) for transmission.

### BACKGROUND

A wireless communications system may include one or multiple network communication devices, which may be otherwise known as network equipment (NE), supporting wireless communications for one or multiple user communication devices, which may be otherwise known as user equipment (UE), or other suitable terminology. The wireless communications system may support wireless communications with one or multiple user communication devices by utilizing resources of the wireless communication system (e.g., time resources (e.g., symbols, slots, subframes, frames, or the like) or frequency resources (e.g., subcarriers, carriers, or the like)). Additionally, the wireless communications system may support wireless communications across various radio access technologies including third generation (3G) radio access technology, fourth generation (4G) radio access technology, fifth generation (5G) radio access technology, among other suitable radio access technologies beyond 5G (e.g., sixth generation (6G)).

### SUMMARY

An article “a” before an element is unrestricted and understood to refer to “at least one” of those elements or “one or more” of those elements. The terms “a,” “at least one,” “one or more,” and “at least one of one or more” may be interchangeable. As used herein, including in the claims, “or” as used in a list of items (e.g., a list of items prefaced by a phrase such as “at least one of” or “one or more of” or “one or both of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.” Further, as used herein, including in the claims, a “set” may include one or more elements.

A UE for wireless communication is described. The UE may be configured to, capable of, or operable to perform one or more operations as described herein. For example, the UE may be configured to, capable of, or operable to obtain data for transmission, the data formable into a transport block (TB) of the data, the TB includes code block groups (CBGs), and each CBG includes one or more code blocks (CBs) that each include a subset of the data, where the CBGs are associated with modulation and coding scheme (MCS) levels of a plurality of MCSs; and transmit a CRC, where the CRC is calculated for the data or a subset of the data in the TB using an MCS level associated with at least one of the CBGs or CBs.

A processor (e.g., a standalone processor chipset, or a component of a UE) for wireless communication is described. The processor may be configured to, capable of, or operable to perform one or more operations as described herein. For example, the processor may be configured to, capable of, or operable to obtain data for transmission, the data formable into a TB of the data, the TB includes CBGs, and each CBG includes one or more CBs that each include a subset of the data, where the CBGs are associated with MCS levels of a plurality of MCSs; and transmit a CRC, where the CRC is calculated for the data or a subset of the data in the TB using an MCS level associated with at least one of the CBGs or CBs.

A method performed or performable by a UE for wireless communication is described. The method may include obtaining data for transmission, the data formable into a TB of the data, the TB includes CBGs, and each CBG includes one or more CBs that each include a subset of the data, where a CBG of the CBGs is associated with a MCS level of a plurality of MCSs; and transmitting a CRC, where the CRC is calculated for the data or a subset of the data in the TB using the MCS level.

In some implementations of the UE, the processor, and the method described herein, the UE, the processor, and the method may be configured to, capable of, or operable to calculate the CRC as at least one of a TB level CRC or a CBG level CRC.

In some implementations of the UE, the processor, and the method described herein, the CRC is a TB level CRC, and the TB level CRC is included in at least one of the CBG or a CB. In some implementations of the UE, the processor, and the method described herein, the TB level CRC is included at a beginning of a first CBG or a first CB of the TB. In some implementations of the UE, the processor, and the method described herein, the MCS level is a lowest MSC level of different MCS levels of the plurality of the MCSs associated with the transmission of the TB. In some implementations of the UE, the processor, and the method described herein, the MCS level is a first indicated value of a plurality of indicated MCS values. In some implementations of the UE, the processor, and the method described herein, the CRC is one or more CBG level CRCs, and the one or more CBG level CRCs are included in respective CBGs of the TB. In some implementations of the UE, the processor, and the method described herein, the one or more CBG level CRCs are associated with a different MCS level of the plurality of the MCSs.

An apparatus (e.g., an NE, a base station) for wireless communication is described. The NE may be configured to, capable of, or operable to perform one or more operations as described herein. For example, the apparatus may be configured to, capable of, or operable to form data into a TB that includes CBGs, each CBG includes one or more CBs that each include a subset of the data, where the CBGs are associated with MCS levels of a plurality of MCSs; and transmit a CRC, where the CRC is calculated for the data or a subset of the data in the TB using an MCS level associated with at least one of the CBGs or CBs.

A processor (e.g., a standalone processor chipset, or a component of an apparatus) for wireless communication is described. The processor may be configured to, capable of, or operable to perform one or more operations as described herein. For example, the processor may be configured to, capable of, or operable to form data into a TB that includes CBGs, each CBG includes one or more CBs that each include a subset of the data, where the CBGs are associated with MCS levels of a plurality of MCSs; and transmit a CRC, where the CRC is calculated for the data or a subset of the data in the TB using an MCS level associated with at least one of the CBGs or CBs.

A method performed or performable by an apparatus (e.g., a base station) for wireless communication is described. The method may include forming data into a TB that includes CBGs, each CBG includes one or more CBs that each include a subset of the data, where the CBGs are associated with MCS levels of a plurality of MCSs; and transmitting a CRC, where the CRC is calculated for the data or a subset of the data in the TB using an MCS level associated with at least one of the CBGs or CBs.

In some implementations of the apparatus, the processor, and the method described herein, the NE, the processor, and the method may be configured to, capable of, or operable to calculate the CRC as at least one of a TB level CRC or a CBG level CRC.

In some implementations of the apparatus, the processor, and the method described herein, the CRC is a TB level CRC, and the TB level CRC is included in at least one of the CBG or a CB. In some implementations of the apparatus, the processor, and the method described herein, the TB level CRC is included at a beginning of a first CBG or a first CB of the TB. In some implementations of the apparatus, the processor, and the method described herein, the MCS level is a lowest MSC level of different MCS levels of the plurality of the MCSs associated with the transmission of the TB. In some implementations of the apparatus, the processor, and the method described herein, the MCS level is a first indicated value of a plurality of indicated MCS values. In some implementations of the apparatus, the processor, and the method described herein, the CRC is one or more CBG level CRCs, and the one or more CBG level CRCs are included in respective CBGs of the TB. In some implementations of the apparatus, the processor, and the method described herein, the one or more CBG level CRCs are associated with a different MCS level of the plurality of the MCSs.

### BRIEF DESCRIPTION OF THE DRAWINGS

FIG. 1 illustrates an example of a wireless communications system in accordance with aspects of the present disclosure.

FIG. 2 illustrates an example of wireless communication, in accordance with aspects of the present disclosure.

FIG. 3 illustrates an example of channel fluctuation, in accordance with aspects of the present disclosure.

FIG. 4 illustrates an example of CRC generation and attachment, in accordance with aspects of the present disclosure.

FIG. 5 illustrates an example of channel coding and multiplexing procedure chain, in accordance with aspects of the present disclosure.

FIG. 6 illustrates an example of a TB, in accordance with aspects of the present disclosure.

FIG. 7 illustrates an example of a TB level CRC attached to a CB or CBG, in accordance with aspects of the present disclosure.

FIG. 8 illustrates another example of a TB level CRC attached to a CB or CBG, in accordance with aspects of the present disclosure.

FIG. 9 illustrates an example of a CBG level CRC attached to a CB or CBG, in accordance with aspects of the present disclosure.

FIG. 10 illustrates an example of a TB level CRC attached to a CB or CBG, in accordance with aspects of the present disclosure.

FIG. 11 illustrates an example of a UE in accordance with aspects of the present disclosure.

FIG. 12 illustrates an example of a processor in accordance with aspects of the present disclosure.

FIG. 13 illustrates an example of an NE in accordance with aspects of the present disclosure.

FIG. 14 illustrates a flowchart of a method performed by a UE in accordance with aspects of the present disclosure.

FIG. 15 illustrates a flowchart of a method performed by an apparatus (e.g., NE, UE, or other device) in accordance with aspects of the present disclosure.

### DETAILED DESCRIPTION

In a wireless communications system, a TB refers to a block of data (e.g., a data payload) communicated (e.g., transmitted, sent, output, received, signaled) between a physical layer and one or more higher layers (e.g., medium access control (MAC) layer). At a transmitter side, the MAC layer organizes data to be communicated as TBs, and the physical layer processes (e.g., encodes, modulates) the TBs for communication. At a receiver side, the physical layer processes (e.g., decodes, demodulates) the communication (e.g., reception, received) signal to extract the TBs, and provides the TBs to the MAC layer. The TB can be divided into multiple smaller blocks referred to as data blocks, CBs, or CBGs, allowing larger amounts of data to be encoded, transmitted, and decoded efficiently. Different data blocks, CBs, and/or CBGs can be grouped into or associated with different logical channels (LCHs), where each LCH can carry different types of data (e.g., control data, user data, signaling data, and so forth). Each LCH can be associated with a different priority, such as higher priority LCHs having higher quality of service (QoS) requirements or settings than lower priority LCHs.

A data block is communicated (e.g., transmitted, sent, signaled) on one or more resource blocks (RBs). An RB refers to a unit of time and frequency resources. For example, for 5G NR, an RB may include twelve (12) subcarriers in the frequency domain and a number of orthogonal frequency division multiplexing (OFDM) symbols in the time domain (e.g., depending on the subcarrier spacing).

Some wireless communications systems, such as 6G systems, may support a bandwidth in a wider range than previous wireless communications systems, such as a bandwidth in the range of approximately 100 megahertz (MHz) or more. In such situations, the radio channel (e.g., depending on the environment and/or deployment) may encounter not only small-scale fluctuations within a few decibels (dB), but may also encounter larger fluctuations. This may be compensated for in link adaptation by selecting a MCS that is adapted to the average link quality over the assigned bandwidth. The resource signaling for 5G NR supports only a single MCS signaling per TB for a downlink resource assignment or an uplink resource grant.

Given the single MCS signaling per TB, current (5G NR) link adaptation cannot exploit frequency ranges with better signal-to-interference-plus-noise ratio (SINR) by a reduced forward error correction (FEC) overhead, nor can it assign a more robust FEC to data mapped on frequency ranges with a poor MCS. This becomes particularly relevant for a case of very narrow beams, where there is no or extremely limited flexibility to assign frequency ranges according to the best channel out of a group of UEs (such as RB range 1 to UE1 with good SINR, RB range 2 to UE2 with good SINR). To utilize the frequency range and prevalent channel conditions better, it is useful to adapt FEC (and modulation) to the offered capacity with a finer granularity than on a TB level. Still, a CRC for error detection purposes is helpful to implement an hybrid automatic repeat request (HARQ) system.

Aspects of this disclosure are related to a wireless communications system. As described herein, the techniques support a TB including a CB and/or one or more CBG(s) using a different MCS, and a UE, an NE, and/or any type of network device or apparatus implements and transmits a CRC in scenarios with multiple MCS assignments for a TB. In one or more implementations, aspects of the described techniques are related to TB CRC attachment, as well as CB segmentation and CB CRC attachment. Aspects of the techniques are related to implementing and transmitting a CRC for the case of multiple MCS assignments for a TB.

In a wireless communications system, a CRC refers to a cyclic redundancy check, which is an error-detecting code used to identify changes to transmitted data. A CRC can be used to verify data integrity. For example, a CRC may add a short check value to blocks of input data based on a remainder of a polynomial division of their contents. This may help ensure the data received matches the transmitted data. A CRC may also be used for error detection. For example, after a CRC is calculated at the transmitter end, the same CRC calculation may be performed at a receiver end to detect any data corruption. If the calculated CRC value at the receiver end matches the transmitted CRC value, the data may be considered error-free.

By performing the described techniques, a device in a wireless communications system may utilize techniques to implement and transmit a CRC for a TB with multiple MCS assignments. The device may transmit or receive different implementations to encode and modulate TB level CRCs. In one example, the device may transmit or receive encoding and modulation of a TB level CRC according to a most robust MCS. In another example, the device may transmit or receive encoding and modulation of a TB level CRC according to a primary MCS level. The primary MCS level may be indicated in downlink control information (DCI). In an additional example, for a simplified encoding process, the device may transmit or receive a placement or configuration of a TB level CRC at a beginning of a TB.

Aspects of the present disclosure are described in the context of a wireless communications system. In the wireless communications system, a UE and an NE (e.g., a base station, gNB, network entity, network node) may support wireless communication, including reception and/or transmission of wireless communication using time-frequency resources. For example, the UE and the NE may support communicating signals (e.g., carrying control information, data, or the like). It should be understood that various terms may be used interchangeably with “communicating,” such as “signaling,” “transmitting,” “receiving,” “outputting,” “forwarding,” “relaying,” “retrieving,” “obtaining,” and so forth.

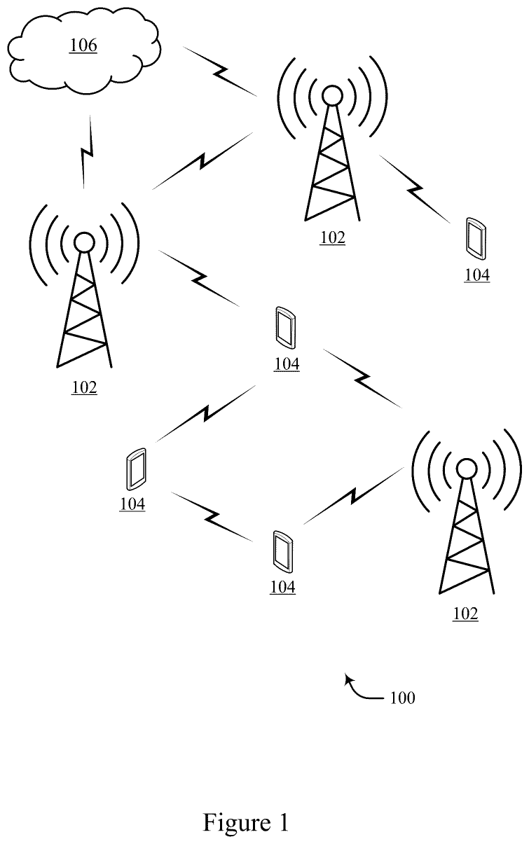

FIG. 1 illustrates an example of a wireless communications system 100 in accordance with aspects of the present disclosure. The wireless communications system 100 may include one or more NEs 102, one or more UEs 104, and a core network (CN) 106. The wireless communications system 100 may support various radio access technologies. In some implementations, the wireless communications system 100 may be a 4G network, such as an LTE network or an LTE-Advanced (LTE-A) network. In some other implementations, the wireless communications system 100 may be a NR network, such as a 5G network, a 5G-Advanced (5G-A) network, or a 5G ultrawideband (5G-UWB) network. In other implementations, the wireless communications system 100 may be a combination of a 4G network and a 5G network, or other suitable radio access technology including Institute of Electrical and Electronics Engineers (IEEE) 802.11 (Wi-Fi), IEEE 802.16 (WiMAX), IEEE 802.20. The wireless communications system 100 may support radio access technologies beyond 5G, for example, 6G. Additionally, the wireless communications system 100 may support technologies, such as time division multiple access (TDMA), frequency division multiple access (FDMA), or code division multiple access (CDMA), etc.

The one or more NEs 102 may be dispersed throughout a geographic region to form the wireless communications system 100. One or more of the NEs 102 described herein may be or include or may be referred to as a network node, a base station, an access point (AP), a network element, a network function, a network entity, network infrastructure (or infrastructure), a radio access network (RAN), a NodeB, an eNodeB (eNB), a next-generation NodeB (gNB), or other suitable terminology. An NE 102 and a UE 104 may communicate via a communication link, which may be a wireless or wired connection. For example, an NE 102 and a UE 104 may perform wireless communication (e.g., receive signaling, transmit signaling) over a Uu interface.

An NE 102 may provide a geographic coverage area for which the NE 102 may support services for one or more UEs 104 within the geographic coverage area. For example, an NE 102 and a UE 104 may support wireless communication of signals related to services (e.g., voice, video, packet data, messaging, broadcast, etc.) according to one or multiple radio access technologies. In some implementations, an NE 102 may be moveable, for example, a satellite associated with a non-terrestrial network (NTN). In some implementations, different geographic coverage areas associated with the same or different radio access technologies may overlap, but the different geographic coverage areas may be associated with different NE 102.

The one or more UEs 104 may be dispersed throughout a geographic region of the wireless communications system 100. A UE 104 may include or may be referred to as a remote unit, a mobile device, a wireless device, a remote device, a subscriber device, a transmitter device, a receiver device, or some other suitable terminology. In some implementations, the UE 104 may be referred to as a unit, a station, a terminal, or a client, among other examples. Additionally, or alternatively, the UE 104 may be referred to as an Internet-of-Things (IoT) device, an Internet-of-Everything (IoE) device, or machine-type communication (MTC) device, among other examples.

A UE 104 may be able to support wireless communication directly with other UEs 104 over a communication link. For example, a UE 104 may support wireless communication directly with another UE 104 over a device-to-device (D2D) communication link. In some implementations, such as vehicle-to-vehicle (V2V) deployments, vehicle-to-everything (V2X) deployments, or cellular-V2X deployments, the communication link may be referred to as a sidelink. For example, a UE 104 may support wireless communication directly with another UE 104 over a PC5 interface.

An NE 102 may support communications with the CN 106, or with another NE 102, or both. For example, an NE 102 may interface with other NE 102 or the CN 106 through one or more backhaul links (e.g., S1, N2, N6, or other network interface). In some implementations, the NE 102 may communicate with each other directly. In some other implementations, the NE 102 may communicate with each other indirectly (e.g., via the CN 106). In some implementations, one or more NEs 102 may include subcomponents, such as an access network entity, which may be an example of an access node controller (ANC). An ANC may communicate with the one or more UEs 104 through one or more other access network transmission entities, which may be referred to as a radio heads, smart radio heads, or transmission-reception points (TRPs).

The CN 106 may support user authentication, access authorization, tracking, connectivity, and other access, routing, or mobility functions. The CN 106 may be an evolved packet core (EPC), or a 5G core (5GC), which may include a control plane entity that manages access and mobility (e.g., a mobility management entity (MME), an access and mobility management functions (AMF)) and a user plane entity that routes packets or interconnects to external networks (e.g., a serving gateway (S-GW), a packet data network (PDN) gateway (P-GW), or a user plane function (UPF)). In some implementations, the control plane entity may manage non-access stratum (NAS) functions, such as mobility, authentication, and bearer management (e.g., data bearers, signal bearers, etc.) for the one or more UEs 104 served by the one or more NEs 102 associated with the CN 106.

The CN 106 may communicate with a packet data network over one or more backhaul links (e.g., via an S1, N2, N6, or other network interface). The packet data network may include an application server. In some implementations, one or more UEs 104 may communicate with the application server. A UE 104 may establish a session (e.g., a protocol data unit (PDU) session, or the like) with the CN 106 via an NE 102. The CN 106 may route traffic (e.g., control information, data, and the like) between the UE 104 and the application server using the established session (e.g., the established PDU session). The PDU session may be an example of a logical connection between the UE 104 and the CN 106 (e.g., one or more network functions of the CN 106).

In the wireless communications system 100, the NEs 102 and the UEs 104 may use resources of the wireless communications system 100 (e.g., time resources (e.g., symbols, slots, subframes, frames, or the like) or frequency resources (e.g., subcarriers, carriers)) to perform various operations (e.g., wireless communications). In some implementations, the NEs 102 and the UEs 104 may support different resource structures. For example, the NEs 102 and the UEs 104 may support different frame structures. In some implementations, such as in 4G, the NEs 102 and the UEs 104 may support a single frame structure. In some other implementations, such as in 5G and among other suitable radio access technologies, the NEs 102 and the UEs 104 may support various frame structures (i.e., multiple frame structures). The NEs 102 and the UEs 104 may support various frame structures based on one or more numerologies.

One or more numerologies may be supported in the wireless communications system 100, and a numerology may include a subcarrier spacing and a cyclic prefix. A first numerology (e.g., μ=0) may be associated with a first subcarrier spacing (e.g., 15 kHz) and a normal cyclic prefix. In some implementations, the first numerology (e.g., μ=0) associated with the first subcarrier spacing (e.g., 15 kHz) may utilize one slot per subframe. A second numerology (e.g., μ=1) may be associated with a second subcarrier spacing (e.g., 30 kHz) and a normal cyclic prefix. A third numerology (e.g., μ=2) may be associated with a third subcarrier spacing (e.g., 60 kHz) and a normal cyclic prefix or an extended cyclic prefix. A fourth numerology (e.g., μ=3) may be associated with a fourth subcarrier spacing (e.g., 120 kHz) and a normal cyclic prefix. A fifth numerology (e.g., μ=4) may be associated with a fifth subcarrier spacing (e.g., 240 kHz) and a normal cyclic prefix.

A time interval of a resource (e.g., a communication resource) may be organized according to frames (also referred to as radio frames). Each frame may have a duration, for example, a 10 millisecond (ms) duration. In some implementations, each frame may include multiple subframes. For example, each frame may include 10 subframes, and each subframe may have a duration, for example, a 1 ms duration. In some implementations, each frame may have the same duration. In some implementations, each subframe of a frame may have the same duration.

Additionally, or alternatively, a time interval of a resource (e.g., a communication resource) may be organized according to slots. For example, a subframe may include a number (e.g., quantity) of slots. The number of slots in each subframe may also depend on the one or more numerologies supported in the wireless communications system 100. For instance, the first, second, third, fourth, and fifth numerologies (i.e., μ=0, μ=1, μ=2, μ=3, μ=4) associated with respective subcarrier spacings of 15 kHz, 30 kHz, 60 kHz, 120 kHz, and 240 kHz may utilize a single slot per subframe, two slots per subframe, four slots per subframe, eight slots per subframe, and 16 slots per subframe, respectively. Each slot may include a number (e.g., quantity) of symbols (e.g., OFDM symbols). In some implementations, the number (e.g., quantity) of slots for a subframe may depend on a numerology. For a normal cyclic prefix, a slot may include 14 symbols. For an extended cyclic prefix (e.g., applicable for 60 kHz subcarrier spacing), a slot may include 12 symbols. The relationship between the number of symbols per slot, the number of slots per subframe, and the number of slots per frame for a normal cyclic prefix and an extended cyclic prefix may depend on a numerology. It should be understood that reference to a first numerology (e.g., μ=0) associated with a first subcarrier spacing (e.g., 15 kHz) may be used interchangeably between subframes and slots.

In the wireless communications system 100, an electromagnetic (EM) spectrum may be split, based on frequency or wavelength, into various classes, frequency bands, frequency channels, etc. By way of example, the wireless communications system 100 may support one or multiple operating frequency bands, such as frequency range designations FR1 (410 MHz-7.125 GHz), FR2 (24.25 GHz-52.6 GHz), FR3 (7.125 GHz-24.25 GHz), FR4 (52.6 GHz-114.25 GHz), FR4a or FR4-1 (52.6 GHz-71 GHz), and FR5 (114.25 GHz-300 GHz). In some implementations, the NEs 102 and the UEs 104 may perform wireless communications over one or more of the operating frequency bands. In some implementations, FR1 may be used by the NEs 102 and the UEs 104, among other equipment or devices for cellular communications traffic (e.g., control information, data). In some implementations, FR2 may be used by the NEs 102 and the UEs 104, among other equipment or devices for short-range, high data rate capabilities.

FR1 may be associated with one or multiple numerologies (e.g., at least three numerologies). For example, FR1 may be associated with a first numerology (e.g., μ=0), which includes 15 kHz subcarrier spacing; a second numerology (e.g., μ=1), which includes 30 kHz subcarrier spacing; and a third numerology (e.g., μ=2), which includes 60 kHz subcarrier spacing. FR2 may be associated with one or multiple numerologies (e.g., at least 2 numerologies). For example, FR2 may be associated with a third numerology (e.g., μ=2), which includes 60 kHz subcarrier spacing; and a fourth numerology (e.g., μ=3), which includes 120 kHz subcarrier spacing.

Some wireless communications systems may support a TB that includes CB and/or CBG(s) using a different MCS. In implementations of the described techniques, an NE 102 and a UE 104 in the wireless communications system 100 may support techniques to implement and transmit a CRC for a TB with multiple MCS assignments. The NE 102 or the UE 104 may transmit or receive different implementations of encoding and modulation of TB level CRC. The NE 102 or the UE 104 may transmit or receive encoding and modulation of TB level CRC according to a most robust MCS or a primary MCS level. In an implementation, the NE 102 or the UE 104 may transmit or receive configuration or placement a TB level CRC at a beginning of a TB.

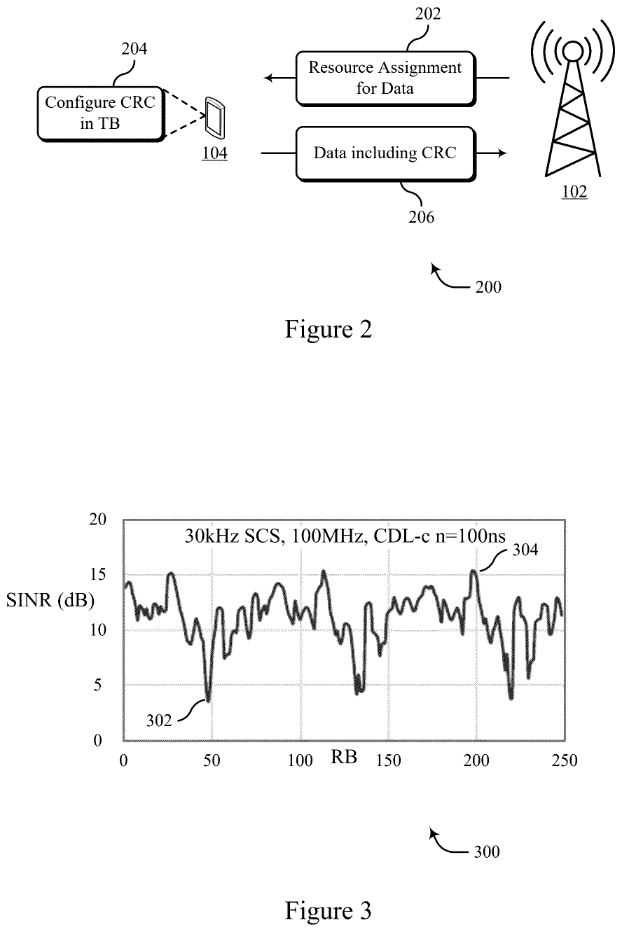

FIG. 2 illustrates an example 200 of wireless communication in accordance with aspects of the present disclosure. In the example 200, an NE 102 communicates (e.g., transmits, sends, signals) a resource assignment for data 202 (e.g., a data transmission) to a UE 104. The UE 104 receives the resource assignment (e.g., obtains the resources on which to transmit data). In one or more implementations, the UE 104 performs a CRC in a TB of the data (at 204), where the TB includes CBGs, and each CBG includes one or more CBs that each include a subset of the data. The CBGs are associated with MCS levels of a plurality of MCSs. The UE 104 communicates (e.g., transmits, sends, signals), to the NE 102, the data and the CRC (206), where the CRC is calculated for the data or a subset of the data in the TB using an MCS level associated with at least one of the CBGs or CBs.

FIG. 3 illustrates an example 300 of channel fluctuation in accordance with aspects of the present disclosure. The example 300 illustrates SINR in a transmit (Tx) wireless communication channel having 30 kilohertz (kHz) subcarrier spacing (SCS) across a 100 MHz bandwidth, using a clustered delay line (CDL) profile CDL-C, where n=100 nanoseconds. As illustrated, the Tx channel has channel fluctuation of greater than 10 dB, such as from approximately 4 dB at 302 to over 15 dB at 304.

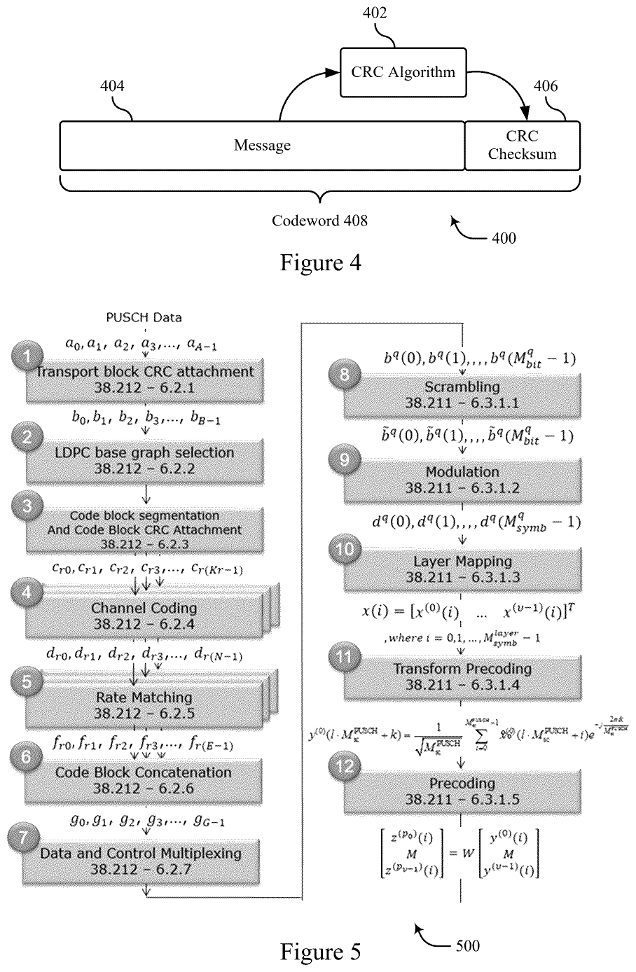

FIG. 4 illustrates an example 400 of CRC generation and attachment in accordance with aspects of the present disclosure. With reference to a TB and CB CRC generation in 5G NR, a CRC algorithm 402 may receive a message 404, such as a first bit sequence, as an input. The output may be the CRC checksum 406, such as a second bit sequence. The message 404 and the CRC checksum 406 may form a codeword 408. The CRC checksum 406 may be traditionally appended to the message 404, resulting in, for example, a third bit sequence, which subsequently is processed further by a forward error correction and modulation step. A CRC is an error-detecting code used to identify changes to transmitted data. The CRC checksum 406 may be used for error detection or to ensure data integrity.

FIG. 5 illustrates an example 500 of a channel coding and multiplexing procedure chain in 5G NR, in accordance with aspects of the present disclosure. With reference to physical uplink shared channel (PUSCH), this example 500 illustrates the channel coding and multiplexing chain and procedures as used in 5G NR on the transmitter side. For purposes of the present disclosure, this example 500 for a PUSCH procedure is equally applicable for a physical downlink shared channel (PDSCH). For example, procedure (1) may be a TB CRC attachment. Procedure (2) may be a low-density parity-check (LDPC) base graph selection. Procedure (3) may be a CB segmentation and a CB CRC attachment. Procedure (4) may be a channel coding. Procedure (5) may be a rate matching. Procedure (6) may be a CB concatenation. Procedure (7) may be a data and control multiplexing. Procedure (8) may be scrambling. Procedure (9) may be a modulation. Procedure (10) may be a layer mapping. Procedure (11) may be a transform precoding. Procedure (12) may be a precoding.

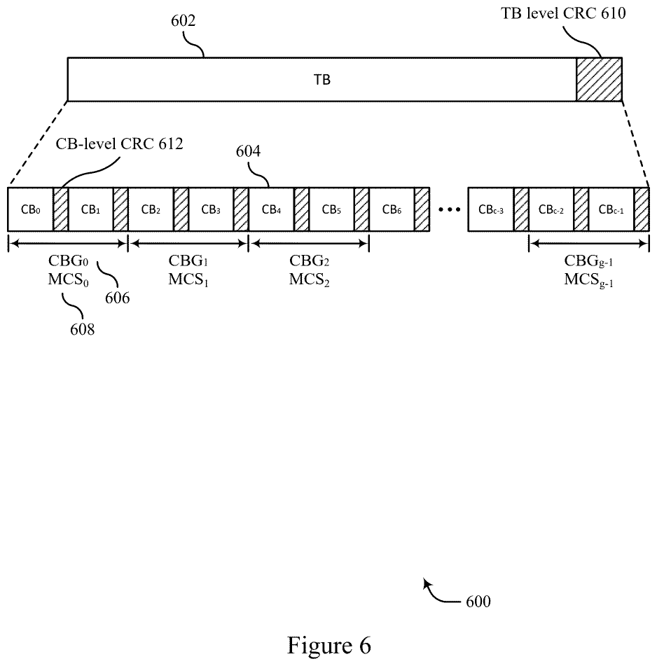

FIG. 6 illustrates an example 600 of a TB in accordance with aspects of the present disclosure. In this example, a TB 602 is TB formed by data to be transmitted, for example, in a MAC layer. The transmission may employ different MCS levels for different parts of the assigned resources. The transmission may also employ different MCS levels for different parts of the TB. In one or more implementations, data being transmitted may be segmented such that all data belonging to the same CB or CBG is associated with the same MCS level. For example, the TB 602 may be segmented to CBs 604 (e.g., CB₀, CB₁, CB₂, CB₃, CB₄, CB₅, and CB₆) and CBGs 606 (e.g., CBG₀, CBG₁, and CBG₂). A first MCS level 608 (e.g., MCS₀) may be associated with the data in CBG₀, a second MCS level (MCS₁) may be associated with the data in CBG₁, a third MCS level (MCS₂) may be associated with the data in CBG₂, and so on.

In one or more implementations, the UE 104 or the NE 102 may attach a TB-level CRC 610 to the CBG with the lowest MCS level out of the plurality of MCS levels used for the transmission for the TB. In another implementation, the UE 104 or the NE 102 may attach the TB-level CRC 610 to a first CBG that employs a reference MCS level. In another implementation, the UE 104 or the NE 102 may omit the TB-level CRC 610 and optionally use a CBG-level CRC 612, in addition to a CB-level CRC for each CBG. In another implementation, the TB-level CRC 610 may be encoded like an independent short CBG that is encoded using the reference MCS level.

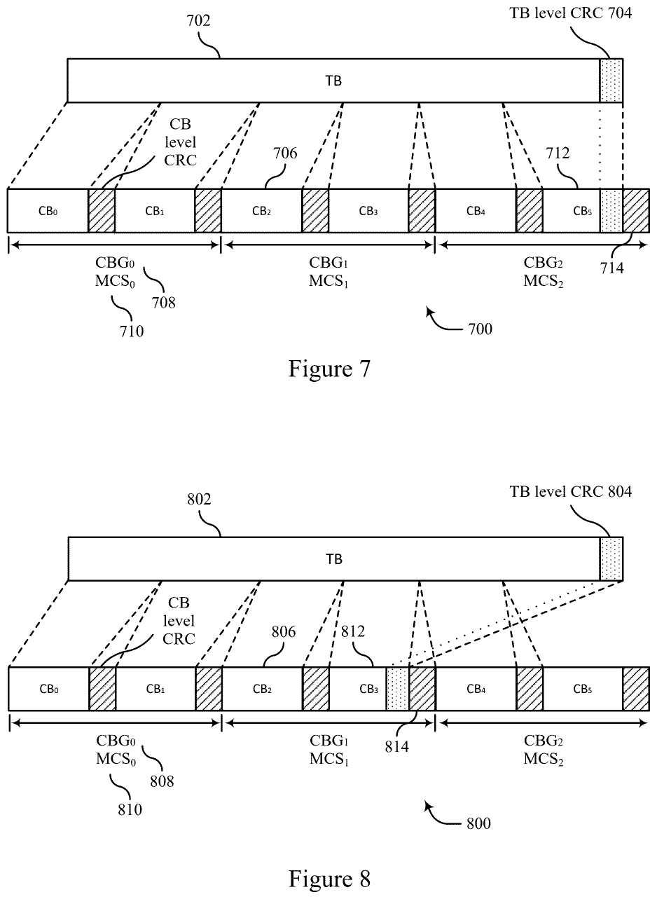

FIG. 7 illustrates an example 700 of a TB level CRC attached to a CB or CBG, in accordance with aspects of the present disclosure. In this example 700, a TB 702 may include a TB level CRC 704. The TB 702 may be segmented into CBs 706 (e.g., CB₀, CB₁, CB₂, CB₃, CB₄, and CB₅) and CBGs 708 (e.g., CBG₀, CBG₁, and CBG₂). A first MCS level 710 (MCS₀) may be associated with the data in CBG₀, a second MCS level (MCS₁) may be associated with the data in CBG₁, a third MCS level (MCS₂) may be associated with the data in CBG₂, and so on.

In an implementation, the TB level CRC 704 may be attached to any of the CBs 706 or a CBG 708 that is associated with a lowest MCS level out of a plurality of MCS levels being used for the data transmission. In this example, the MCS₂ may be the lowest MCS level compared to MCS₀ and MCS₁, and is associated with CB₄ and CB₅ 712 (e.g., also CBG₂). Consequently, the TB level CRC 704 may be included as part of the CBG₂ data, and in this case, may form the last part of CB₅ prior to a CB level CRC 714 calculation and attachment to CB₅. In this way, the TB level CRC 704 may be processed together with CB₅ 712 data. For example, the CRC for CB₅ may be calculated to include the TB level CRC bits, and the CRC for CB₅ may be transmitted using MCS₂ as for all data pertaining to CBG₂.

FIG. 8 illustrates another example 800 of a TB level CRC attached to a CB or CBG, in accordance with aspects of the present disclosure. In this example 800, a TB 802 may include a TB level CRC 804. The TB 802 may be segmented into CBs 806 (e.g., CB₀, CB₁, CB₂, CB₃, CB₄, and CB₅) and CBGs 808 (e.g., CBG₀, CBG₁, and CBG₂). A first MCS level 810 (MCS₀) may be associated with the data in CBG₀, a second MCS level (MCS₁) may be associated with the data in CBG₁, a third MCS level (MCS₂) may be associated with the data in CBG₂, and so on.

In an implementation, the TB level CRC 804 may be attached to any of the CBs 806 or a CBG 808 that is associated with a lowest MCS level out of a plurality of MCS levels being used for the data transmission. In this example, the MCS₁ may be the lowest MCS level compared to MCS₀ and MCS₂, and is associated with CB₂ and CB₃ 812 (e.g., also CBG₁). Consequently, the TB level CRC 804 may be included as part of the CBG₁ data, and in this case may form the last part of CB₃ prior to CB level CRC 814 calculation and attachment to CB₃. In this way, the TB level CRC 804 may be processed together with CB₃ 812 data. For example, the CRC for CB₃ may be calculated to include the TB level CRC bits, and the CRC for CB₃ may be transmitted using MCS₁ as for all data pertaining to CBG₁.

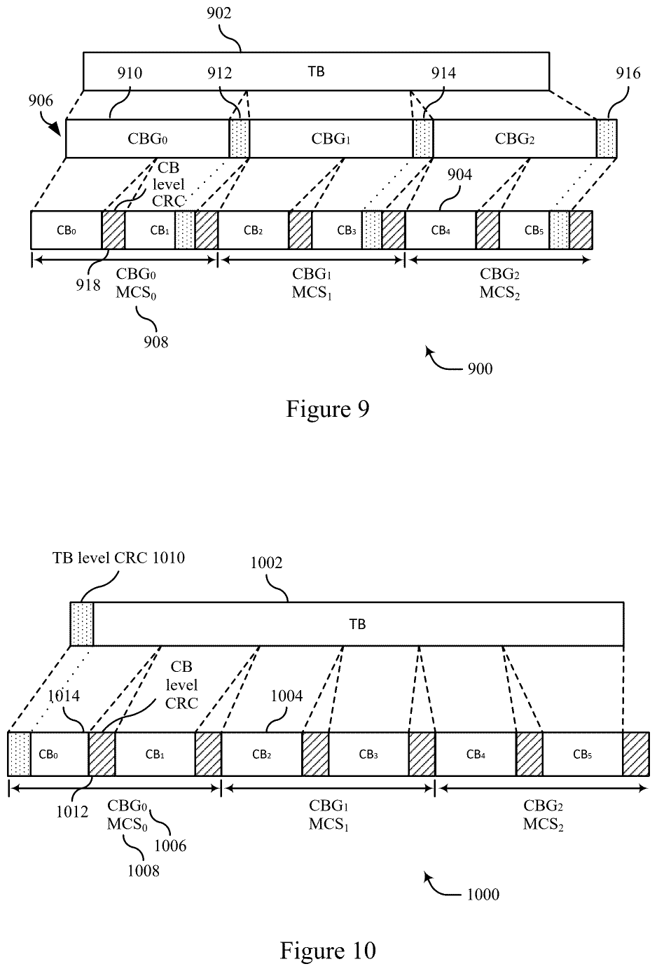

FIG. 9 illustrates an example 900 of a CBG level CRC attached to a CB or CBG, in accordance with aspects of the present disclosure. In this example 900, a TB 902 may be segmented into CBs 904 (e.g., CB₀, CB₁, CB₂, CB₃, CB₄, and CB₅) and CBGs 906 (CBG₀, CBG₁, and CBG₂). A first MCS level 908 (MCS₀) may be associated with the data in CBG₀ 910, a second MCS level (MCS₁) may be associated with the data in CBG₁, a third MCS level (MCS₂) may be associated with the data in CBG₂, and so on.

In an implementation, there may not be a TB level CRC. Instead, a CBG level CRC may be attached to each CBG, where a CBG is associated with one MCS level. For example, a CBG level CRC 912 may be attached to CBG₀, a CBG level CRC 914 may be attached to CBG₁, and a CBG level CRC 916 may be attached to CBG₂. The CBG data plus CBG CRC may then be processed, for example, by CB segmentation, channel coding, and/or modulation steps. For example, a TB may be segmented into the CBGs (CBG₀, CBG₁, and CBG₂), and the first MCS level (MCS₀) is associated with the data in CBG₀, a second MCS level (MCS₁) is associated with the data in CBG₁, and a third MCS level (MCS₂) is associated with the data in CBG₂. Then for each CBG, a CRC may be calculated from the data of that CBG, for example, independently from data of other CBGs. For example, the CBG level CRC 912 may be calculated from the data of CBG₀, the CBG level CRC 914 may be calculated from the data of CBG₁, and the CBG level CRC 916 may be calculated from the data of CBG₂.

Optionally, a CBG may be further segmented to one or more CBs, and each CB within a CBG may have a CB level CRC attached (e.g., CB level CRC 918). Each CBG may be further segmented into CBs (e.g., two CBs). For example, CBG₀ may be segmented into CB₀ and CB₁. Consequently, the CBG₀ level CRC may form the last part of CB₁ prior to CB level CRC calculation and attachment to CB₁. The CBG₁ level CRC may form the last part of CB₃ prior to CB level CRC calculation and attachment to CB₃. And the CBG₂ level CRC may form the last part of CB₅ prior to CB level CRC calculation and attachment to CB₅.

FIG. 10 illustrates an example 1000 of a TB level CRC attached to a CB or CBG, in accordance with aspects of the present disclosure. In this example 1000, a TB 1002 may be segmented to CBs 1004 (e.g., CB₀, CB₁, CB₂, CB₃, CB₄, and CB₅) and CBGs 1006 (CBG₀, CBG₁, and CBG₂). A first MCS level 1008 (MCS₀) may be associated with the data in CBG₀, a second MCS level (MCS₁) may be associated with the data in CBG₁, a third MCS level (MCS₂) may be associated with the data in CBG₂, and so on.

In an implementation, the transmission may be associated with a primary MCS level and one or more secondary MCS levels. The primary MCS level may be an MCS level that is applied to a part of the data (such as one or more CBs/CBGs) within the TB 1002 unless a secondary MCS level is associated with that part of the data. In this case, the TB level CRC 1010 may be associated with the primary MCS level and is correspondingly processed by the transmitter and receiver. In an example, the primary MCS level is the first MCS level indicated by a scheduling indication, such as a DCI for a downlink or an uplink transmission. In an implementation, the TB level CRC 1010 is attached to one of the parts of the data (such as one or more CBs/CBGs) that is being associated with the primary MCS level.

For example, MCS₀ may be the primary MCS level associated with the data part forming CBG₀, and MCS₁ and MCS₂ are secondary MCS levels associated with the data parts forming CBG₁ and CBG₂, respectively. The TB level CRC 1010 may be calculated for all data of the TB, and then may be included with the data part forming CBG₀, for example, the CB/CBG associated with the primary MCS level. This may be accomplished by prepending the TB level CRC 1010 to the TB data prior to segmentation of data to CBGs. The TB level CRC may form part of CB₀ and may be accordingly used for calculation of the CB₀ level CRC 1012, which is appended to CB₀ 1014 for further processing, such as channel coding, rate matching, and/or modulation. Prepending the TB level CRC to the TB data may have the advantage that further processing steps are streamlined assuming that CB₀/CBG0 are₀ associated with the primary MCS level.

With reference to receiver implementations, the procedures and processes described herein may be reversely applied in the receiver. For example, according to the one or more implementations described above, the TB level CRC may be extracted after demodulation and decoding of the CB/CBG associated with the primary MCS, and may be then employed to verify if the TB level CRC matches the CRC calculated from remaining data (excluding e.g., CB/CBG level CRCs) obtained after demodulation and decoding of all CBs and/or CBGs.

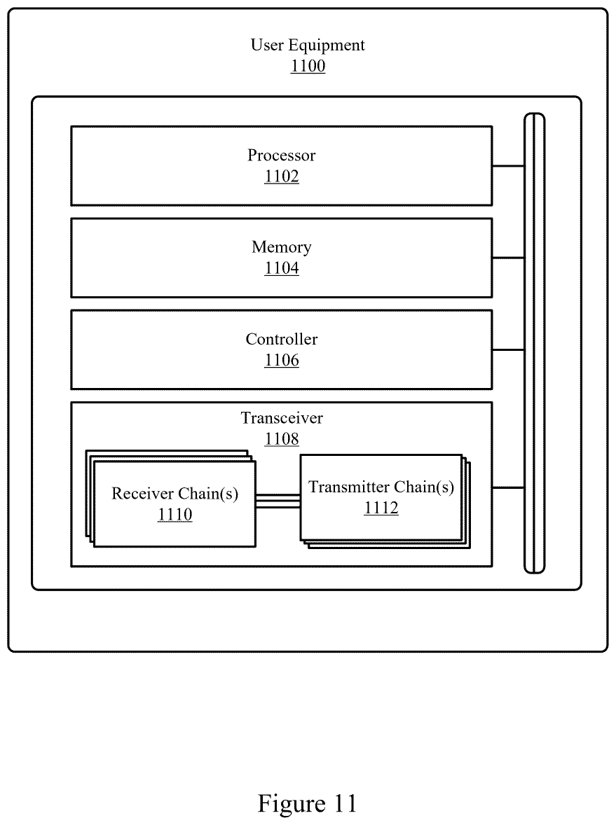

FIG. 11 illustrates an example of a UE 1100 in accordance with aspects of the present disclosure. The UE 1100 may include a processor 1102, a memory 1104, a controller 1106, and a transceiver 1108. The processor 1102, the memory 1104, the controller 1106, or the transceiver 1108, or various combinations thereof or various components thereof may be examples of means for performing various aspects of the present disclosure as described herein. These components may be coupled (e.g., operatively, communicatively, functionally, electronically, electrically) via one or more interfaces.

The processor 1102, the memory 1104, the controller 1106, or the transceiver 1108, or various combinations or components thereof may be implemented in hardware (e.g., circuitry). The hardware may include a processor, a digital signal processor (DSP), an application-specific integrated circuit (ASIC), or other programmable logic device, or any combination thereof configured as or otherwise supporting a means for performing the functions described in the present disclosure.

The processor 1102 may include an intelligent hardware device (e.g., a general-purpose processor, a DSP, a CPU, an ASIC, an FPGA, or any combination thereof). In some implementations, the processor 1102 may be configured to operate the memory 1104. In some other implementations, the memory 1104 may be integrated into the processor 1102. The processor 1102 may be configured to execute computer-readable instructions stored in the memory 1104 to cause the UE 1100 to perform various functions of the present disclosure.

The memory 1104 may include volatile or non-volatile memory. The memory 1104 may store computer-readable, computer-executable code including instructions when executed by the processor 1102 cause the UE 1100 to perform various functions described herein. The code may be stored in a non-transitory computer-readable medium such as the memory 1104 or another type of memory. Computer-readable media includes both non-transitory computer storage media and communication media including any medium that facilitates transfer of a computer program from one place to another. A non-transitory storage medium may be any available medium that may be accessed by a general-purpose or special-purpose computer.

In some implementations, the processor 1102 and the memory 1104 coupled with the processor 1102 may be configured to or operable to cause the UE 1100 to perform one or more of the functions described herein (e.g., executing, by the processor 1102, instructions stored in the memory 1104). For example, the processor 1102 may support wireless communication at the UE 1100 in accordance with examples as disclosed herein. The UE 1100 may be configured to or operable to support a means for obtaining data for transmission, the data formable into a TB of the data, the TB includes CBGs, and each CBG includes one or more CBs that each include a subset of the data, where a CBG of the CBGs is associated with a MCS level of a plurality of MCSs; and transmitting a CRC, where the CRC is calculated for the data or a subset of the data in the TB using the MCS level.

Additionally, the UE 1100 may be configured to or operable to support any one or combination of the method further including calculating the CRC as at least one of a TB level CRC or a CBG level CRC. The CRC is a TB level CRC, and the TB level CRC is included in at least one of the CBG or a CB. The TB level CRC is included at a beginning of a first CBG or a first CB of the TB. The MCS level is a lowest MSC level of different MCS levels of the plurality of the MCSs associated with the transmission of the TB. The MCS level is a first indicated value of a plurality of indicated MCS values. The CRC is one or more CBG level CRCs, and the one or more CBG level CRCs are included in respective CBGs of the TB. The one or more CBG level CRCs are associated with a different MCS level of the plurality of the MCSs.

Additionally, or alternatively, the UE 1100 may support at least one memory (e.g., the memory 1104) and at least one processor (e.g., the processor 1102) coupled with the at least one memory and configured to or operable to cause the UE to obtain data for transmission, the data formable into a TB of the data, the TB includes CBGs, and each CBG includes one or more CBs that each include a subset of the data, where the CBGs are associated with MCS levels of a plurality of MCSs; and transmit a CRC, where the CRC is calculated for the data or a subset of the data in the TB using an MCS level associated with at least one of the CBGs or CBs.

Additionally, the UE 1100 may be configured to or operable to support any one or combination of the at least one processor is operable to cause the UE to calculate the CRC as at least one of a TB level CRC or a CBG level CRC. The CRC is a TB level CRC, and the TB level CRC is included in at least one of the CBG or a CB. The TB level CRC is included at a beginning of a first CBG or a first CB of the TB. The MCS level is a lowest MSC level of different MCS levels of the plurality of the MCSs associated with the transmission of the TB. The MCS level is a first indicated value of a plurality of indicated MCS values. The CRC is one or more CBG level CRCs, and the one or more CBG level CRCs are included in respective CBGs of the TB. The one or more CBG level CRCs are associated with a different MCS level of the plurality of the MCSs.

The controller 1106 may manage input and output signals for the UE 1100. The controller 1106 may also manage peripherals not integrated into the UE 1100. In some implementations, the controller 1106 may utilize an operating system such as iOS®, ANDROID®, WINDOWS®, or other operating systems. In some implementations, the controller 1106 may be implemented as part of the processor 1102.

In some implementations, the UE 1100 may include at least one transceiver 1108. In some other implementations, the UE 1100 may have more than one transceiver 1108. The transceiver 1108 may represent a wireless transceiver. The transceiver 1108 may include one or more receiver chains 1110, one or more transmitter chains 1112, or a combination thereof.

A receiver chain 1110 may be configured to receive signals (e.g., control information, data, packets) over a wireless medium. For example, the receiver chain 1110 may include one or more antennas to receive a signal over the air or wireless medium. The receiver chain 1110 may include at least one amplifier (e.g., a low-noise amplifier (LNA)) configured to amplify the received signal. The receiver chain 1110 may include at least one demodulator configured to demodulate the receive signal and obtain the transmitted data by reversing the modulation technique applied during transmission of the signal. The receiver chain 1110 may include at least one decoder for decoding the demodulated signal to receive the transmitted data.

A transmitter chain 1112 may be configured to generate and transmit signals (e.g., control information, data, packets). The transmitter chain 1112 may include at least one modulator for modulating data onto a carrier signal, preparing the signal for transmission over a wireless medium. The at least one modulator may be configured to support one or more techniques such as amplitude modulation (AM), frequency modulation (FM), or digital modulation schemes like phase-shift keying (PSK) or quadrature amplitude modulation (QAM). The transmitter chain 1112 may also include at least one power amplifier configured to amplify the modulated signal to an appropriate power level suitable for transmission over the wireless medium. The transmitter chain 1112 may also include one or more antennas for transmitting the amplified signal into the air or wireless medium.

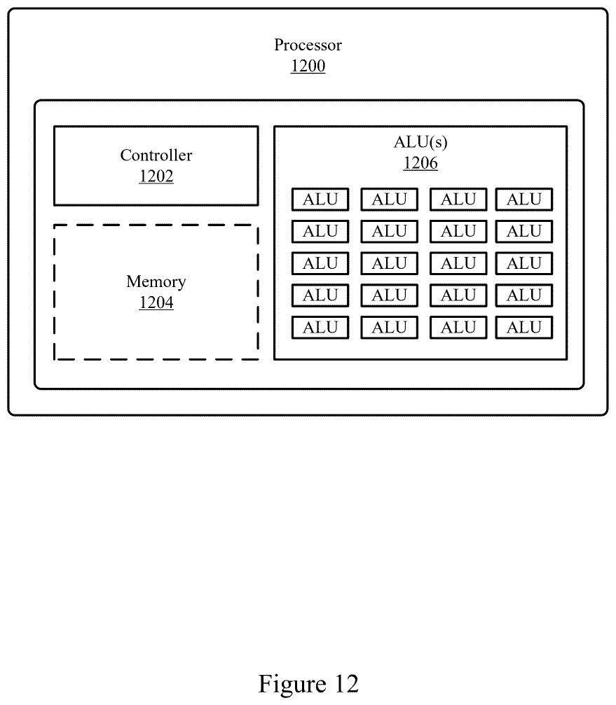

FIG. 12 illustrates an example of a processor 1200 in accordance with aspects of the present disclosure. The processor 1200 may be an example of a processor configured to perform various operations in accordance with examples as described herein. The processor 1200 may include a controller 1202 configured to perform various operations in accordance with examples as described herein. The processor 1200 may optionally include at least one memory 1204, which may be, for example, an L1/L2/L3 cache. Additionally, or alternatively, the processor 1200 may optionally include one or more arithmetic-logic units (ALUs) 1206. One or more of these components may be in electronic communication or otherwise coupled (e.g., operatively, communicatively, functionally, electronically, electrically) via one or more interfaces (e.g., buses).

The processor 1200 may be a processor chipset and include a protocol stack (e.g., a software stack) executed by the processor chipset to perform various operations (e.g., receiving, obtaining, retrieving, transmitting, outputting, forwarding, storing, determining, identifying, accessing, writing, reading) in accordance with examples as described herein. The processor chipset may include one or more cores, one or more caches (e.g., memory local to or included in the processor chipset (e.g., the processor 1200) or other memory (e.g., random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), and others).

The controller 1202 may be configured to manage and coordinate various operations (e.g., signaling, receiving, obtaining, retrieving, transmitting, outputting, forwarding, storing, determining, identifying, accessing, writing, reading) of the processor 1200 to cause the processor 1200 to support various operations in accordance with examples as described herein. For example, the controller 1202 may operate as a control unit of the processor 1200, generating control signals that manage the operation of various components of the processor 1200. These control signals include enabling or disabling functional units, selecting data paths, initiating memory access, and coordinating timing of operations.

The controller 1202 may be configured to fetch (e.g., obtain, retrieve, receive) instructions from the memory 1204 and determine subsequent instruction(s) to be executed to cause the processor 1200 to support various operations in accordance with examples as described herein. The controller 1202 may be configured to track memory addresses of instructions associated with the memory 1204. The controller 1202 may be configured to decode instructions to determine the operation to be performed and the operands involved. For example, the controller 1202 may be configured to interpret the instruction and determine control signals to be output to other components of the processor 1200 to cause the processor 1200 to support various operations in accordance with examples as described herein. Additionally, or alternatively, the controller 1202 may be configured to manage flow of data within the processor 1200. The controller 1202 may be configured to control transfer of data between registers, ALUs 1206, and other functional units of the processor 1200.

The memory 1204 may include one or more caches (e.g., memory local to or included in the processor 1200 or other memory, such as RAM, ROM, DRAM, SDRAM, SRAM, MRAM, flash memory, etc. In some implementations, the memory 1204 may reside within or on a processor chipset (e.g., local to the processor 1200). In some other implementations, the memory 1204 may reside external to the processor chipset (e.g., remote to the processor 1200).

The memory 1204 may store computer-readable, computer-executable code including instructions that, when executed by the processor 1200, cause the processor 1200 to perform various functions described herein. The code may be stored in a non-transitory computer-readable medium such as system memory or another type of memory. The controller 1202 and/or the processor 1200 may be configured to execute computer-readable instructions stored in the memory 1204 to cause the processor 1200 to perform various functions. For example, the processor 1200 and/or the controller 1202 may be coupled with or to the memory 1204, the processor 1200, and the controller 1202, and may be configured to perform various functions described herein. In some examples, the processor 1200 may include multiple processors and the memory 1204 may include multiple memories. One or more of the multiple processors may be coupled with one or more of the multiple memories, which may, individually or collectively, be configured to perform various functions herein.

The one or more ALUs 1206 may be configured to support various operations in accordance with examples as described herein. In some implementations, the one or more ALUs 1206 may reside within or on a processor chipset (e.g., the processor 1200). In some other implementations, the one or more ALUs 1206 may reside external to the processor chipset (e.g., the processor 1200). One or more ALUs 1206 may perform one or more computations such as addition, subtraction, multiplication, and division on data. For example, one or more ALUs 1206 may receive input operands and an operation code, which determines an operation to be executed. One or more ALUs 1206 may be configured with a variety of logical and arithmetic circuits, including adders, subtractors, shifters, and logic gates, to process and manipulate the data according to the operation. Additionally, or alternatively, the one or more ALUs 1206 may support logical operations such as AND, OR, exclusive-OR (XOR), not-OR (NOR), and not-AND (NAND), enabling the one or more ALUs 1206 to handle conditional operations, comparisons, and bitwise operations.

The processor 1200 may support wireless communication in accordance with examples as disclosed herein. The processor 1200 may be configured to support at least one controller (e.g., the controller 1202) coupled with at least one memory (e.g., the memory 1204) and configured to or operable to cause the processor to obtain data for transmission, the data formable into a TB of the data, the TB includes CBGs, and each CBG includes one or more CBs that each include a subset of the data, where the CBGs are associated with MCS levels of a plurality of MCSs; and transmit a CRC, where the CRC is calculated for the data or a subset of the data in the TB using an MCS level associated with at least one of the CBGs or CBs.

Additionally, the processor 1200 may be configured to or operable to support any one or combination of the at least one controller is operable to cause the processor to calculate the CRC as at least one of a TB level CRC or a CBG level CRC. The CRC is a TB level CRC, and the TB level CRC is included in at least one of the CBG or a CB. The TB level CRC is included at a beginning of a first CBG or a first CB of the TB. The MCS level is a lowest MSC level of different MCS levels of the plurality of the MCSs associated with the transmission of the TB. The MCS level is a first indicated value of a plurality of indicated MCS values. The CRC is one or more CBG level CRCs, and the one or more CBG level CRCs are included in respective CBGs of the TB. The one or more CBG level CRCs are associated with a different MCS level of the plurality of the MCSs.

The processor 1200 may support wireless communication in accordance with examples as disclosed herein. The processor 1200 may be configured to support at least one controller (e.g., the controller 1202) coupled with at least one memory (e.g., the memory 1204) and configured to or operable to cause the processor to form data into a TB that includes CBGs, each CBG includes one or more CBs that each include a subset of the data, where the CBGs are associated with MCS levels of a plurality of MCSs; and transmit a CRC, where the CRC is calculated for the data or a subset of the data in the TB using an MCS level associated with at least one of the CBGs or CBs.

Additionally, the processor 1200 may be configured to or operable to support any one or combination of the at least one controller is operable to cause the processor to calculate the CRC as at least one of a TB level CRC or a CBG level CRC. The CRC is a TB level CRC, and the TB level CRC is included in at least one of the CBG or a CB. The TB level CRC is included at a beginning of a first CBG or a first CB of the TB. The MCS level is a lowest MSC level of different MCS levels of the plurality of the MCSs associated with the transmission of the TB. The MCS level is a first indicated value of a plurality of indicated MCS values. The CRC is one or more CBG level CRCs, and the one or more CBG level CRCs are included in respective CBGs of the TB. The one or more CBG level CRCs are associated with a different MCS level of the plurality of the MCSs.

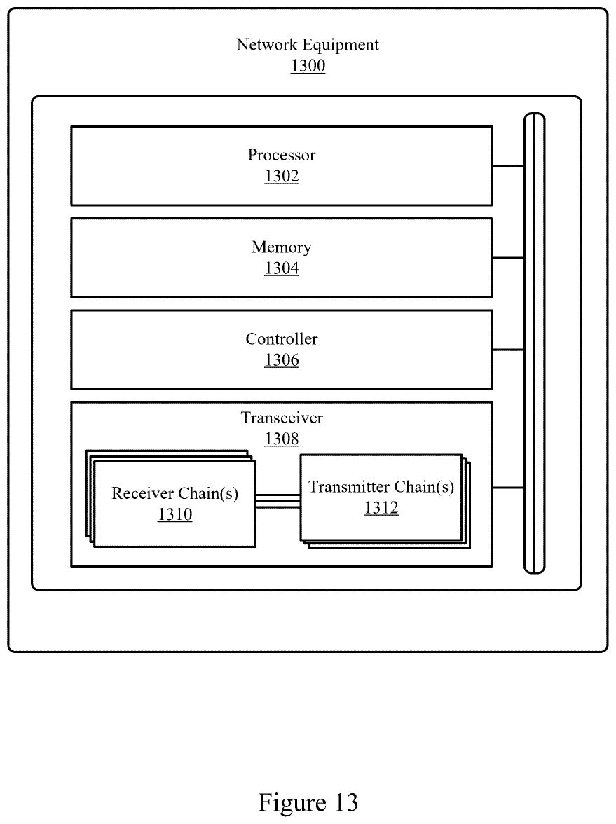

FIG. 13 illustrates an example of an NE 1300 in accordance with aspects of the present disclosure. In one or more implementations, the NE 1300 is an example of an apparatus. The NE 1300 may include a processor 1302, a memory 1304, a controller 1306, and a transceiver 1308. The processor 1302, the memory 1304, the controller 1306, or the transceiver 1308, or various combinations thereof or various components thereof may be examples of means for performing various aspects of the present disclosure as described herein. These components may be coupled (e.g., operatively, communicatively, functionally, electronically, electrically) via one or more interfaces.

The processor 1302, the memory 1304, the controller 1306, or the transceiver 1308, or various combinations or components thereof may be implemented in hardware (e.g., circuitry). The hardware may include a processor, a digital signal processor (DSP), an application-specific integrated circuit (ASIC), or other programmable logic device, or any combination thereof configured as or otherwise supporting a means for performing the functions described in the present disclosure.

The processor 1302 may include an intelligent hardware device (e.g., a general-purpose processor, a DSP, a CPU, an ASIC, an FPGA, or any combination thereof). In some implementations, the processor 1302 may be configured to operate the memory 1304. In some other implementations, the memory 1304 may be integrated into the processor 1302. The processor 1302 may be configured to execute computer-readable instructions stored in the memory 1304 to cause the NE 1300 to perform various functions of the present disclosure.

The memory 1304 may include volatile or non-volatile memory. The memory 1304 may store computer-readable, computer-executable code including instructions when executed by the processor 1302 cause the NE 1300 to perform various functions described herein. The code may be stored in a non-transitory computer-readable medium such as the memory 1304 or another type of memory. Computer-readable media includes both non-transitory computer storage media and communication media including any medium that facilitates transfer of a computer program from one place to another. A non-transitory storage medium may be any available medium that may be accessed by a general-purpose or special-purpose computer.

In some implementations, the processor 1302 and the memory 1304 coupled with the processor 1302 may be configured to cause the NE 1300 to perform one or more of the functions described herein (e.g., executing, by the processor 1302, instructions stored in the memory 1304). For example, the processor 1302 may support wireless communication at the NE 1300 in accordance with examples as disclosed herein. The NE 1300 may be configured to or operable to support a means for forming data into a TB that includes CBGs, each CBG includes one or more CBs that each include a subset of the data, where the CBGs are associated with MCS levels of a plurality of MCSs; and transmitting a CRC, where the CRC is calculated for the data or a subset of the data in the TB using an MCS level associated with at least one of the CBGs or CBs.

Additionally, the NE 1300 may be configured to or operable to support any one or combination of the method further including calculating the CRC as at least one of a TB level CRC or a CBG level CRC. The CRC is a TB level CRC, and the TB level CRC is included in at least one of the CBG or a CB. The TB level CRC is included at a beginning of a first CBG or a first CB of the TB. The MCS level is a lowest MSC level of different MCS levels of the plurality of the MCSs associated with the transmission of the TB. The MCS level is a first indicated value of a plurality of indicated MCS values. The CRC is one or more CBG level CRCs, and the one or more CBG level CRCs are included in respective CBGs of the TB. The one or more CBG level CRCs are associated with a different MCS level of the plurality of the MCSs.

Additionally, or alternatively, the NE 1300 may support at least one memory (e.g., the memory 1304) and at least one processor (e.g., the processor 1302) coupled with the at least one memory and configured to or operable to cause the NE to form data into a TB that includes CBGs, each CBG includes one or more CBs that each include a subset of the data, where the CBGs are associated with MCS levels of a plurality of MCSs; and transmit a CRC, where the CRC is calculated for the data or a subset of the data in the TB using an MCS level associated with at least one of the CBGs or CBs.

Additionally, the NE 1300 may be configured to or operable to support any one or combination of the at least one processor is operable to cause the apparatus to calculate the CRC as at least one of a TB level CRC or a CBG level CRC. The CRC is a TB level CRC, and the TB level CRC is included in at least one of the CBG or a CB. The TB level CRC is included at a beginning of a first CBG or a first CB of the TB. The MCS level is a lowest MSC level of different MCS levels of the plurality of the MCSs associated with the transmission of the TB. The MCS level is a first indicated value of a plurality of indicated MCS values. The CRC is one or more CBG level CRCs, and the one or more CBG level CRCs are included in respective CBGs of the TB. The one or more CBG level CRCs are associated with a different MCS level of the plurality of the MCSs.

The controller 1306 may manage input and output signals for the NE 1300. The controller 1306 may also manage peripherals not integrated into the NE 1300. In some implementations, the controller 1306 may utilize an operating system such as iOS®, ANDROID®, WINDOWS®, or other operating systems. In some implementations, the controller 1306 may be implemented as part of the processor 1302.

In some implementations, the NE 1300 may include at least one transceiver 1308. In some other implementations, the NE 1300 may have more than one transceiver 1308. The transceiver 1308 may represent a wireless transceiver. The transceiver 1308 may include one or more receiver chains 1310, one or more transmitter chains 1312, or a combination thereof.

A receiver chain 1310 may be configured to receive signals (e.g., control information, data, packets) over a wireless medium. For example, the receiver chain 1310 may include one or more antennas to receive a signal over the air or wireless medium. The receiver chain 1310 may include at least one amplifier (e.g., a low-noise amplifier (LNA)) configured to amplify the received signal. The receiver chain 1310 may include at least one demodulator configured to demodulate the receive signal and obtain the transmitted data by reversing the modulation technique applied during transmission of the signal. The receiver chain 1310 may include at least one decoder for decoding the demodulated signal to receive the transmitted data.

A transmitter chain 1312 may be configured to generate and transmit signals (e.g., control information, data, packets). The transmitter chain 1312 may include at least one modulator for modulating data onto a carrier signal, preparing the signal for transmission over a wireless medium. The at least one modulator may be configured to support one or more techniques such as amplitude modulation (AM), frequency modulation (FM), or digital modulation schemes like phase-shift keying (PSK) or quadrature amplitude modulation (QAM). The transmitter chain 1312 may also include at least one power amplifier configured to amplify the modulated signal to an appropriate power level suitable for transmission over the wireless medium. The transmitter chain 1312 may also include one or more antennas for transmitting the amplified signal into the air or wireless medium.

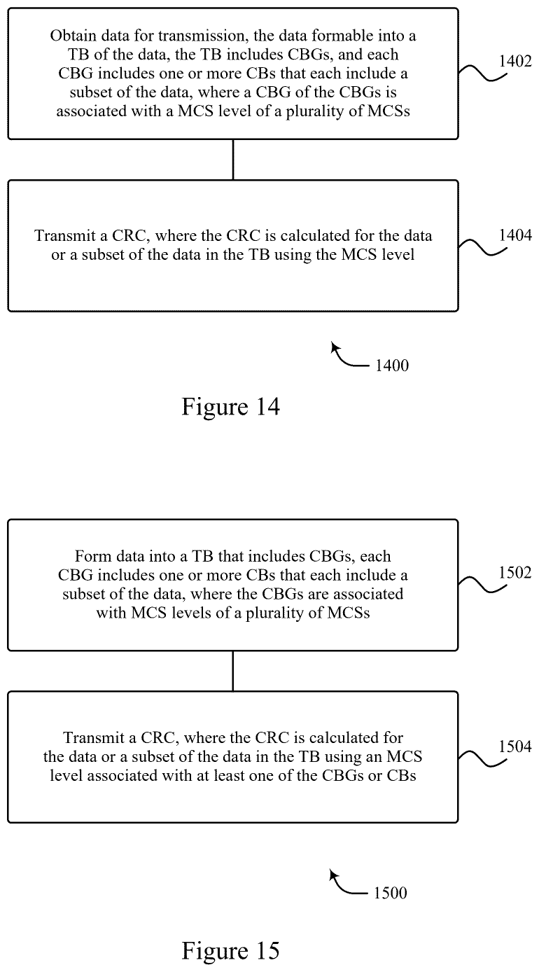

FIG. 14 illustrates a flowchart of a method 1400 in accordance with aspects of the present disclosure. The operations of the method may be implemented by a UE as described herein. In some implementations, the UE may execute a set of instructions to control the function elements of the UE to perform the described functions. It should be noted that the method described herein describes a possible implementation, and that the operations and the steps may be rearranged or otherwise modified and that other implementations are possible.

At 1402, the method may include obtaining data for transmission, the data formable into a TB of the data, the TB includes CBGs, and each CBG includes one or more CBs that each include a subset of the data, where a CBG of the CBGs is associated with a MCS level of a plurality of MCSs. The operations of 1402 may be performed in accordance with examples as described herein. In some implementations, aspects of the operations of 1402 may be performed by a UE as described with reference to FIG. 11.

At 1404, the method may include transmitting a CRC, where the CRC is calculated for the data or a subset of the data in the TB using the MCS level. The operations of 1404 may be performed in accordance with examples as described herein. In some implementations, aspects of the operations of 1404 may be performed by a UE as described with reference to FIG. 11.

FIG. 15 illustrates a flowchart of a method 1500 in accordance with aspects of the present disclosure. The operations of the method may be implemented by an apparatus (e.g., NE, UE, or other device) as described herein. In some implementations, the apparatus may execute a set of instructions to control the function elements of the NE to perform the described functions. It should be noted that the method described herein describes a possible implementation, and that the operations and the steps may be rearranged or otherwise modified and that other implementations are possible.

At 1502, the method may include forming data into a TB that is CBGs, each CBG includes one or more CBs that each include a subset of the data, where the CBGs are associated with MCS levels of a plurality of MCSs. The operations of 1502 may be performed in accordance with examples as described herein. In some implementations, aspects of the operations of 1502 may be performed by an apparatus (e.g., NE) as described with reference to FIG. 13.

At 1504, the method may include transmitting a CRC, where the CRC is calculated for the data or a subset of the data in the TB using an MCS level associated with at least one of the CBGs or CBs. The operations of 1504 may be performed in accordance with examples as described herein. In some implementations, aspects of the operations of 1504 may be performed by an apparatus (e.g., NE) as described with reference to FIG. 13.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A user equipment (UE) for wireless communication, comprising:
at least one memory; and
at least one processor coupled with the at least one memory and operable to cause the UE to:
obtain data for transmission, the data formable into a transport block (TB) of the data, the TB comprised of code block groups (CBGs), and each CBG comprises one or more code blocks (CBs) that each include a subset of the data, wherein the CBGs are associated with modulation and coding scheme (MCS) levels of a plurality of MCSs; and
transmit a cyclic redundancy check (CRC), wherein the CRC is calculated for the data or a subset of the data in the TB using an MCS level associated with at least one of the CBGs or CBs.

2. The UE of claim 1, wherein the at least one processor is operable to cause the UE to calculate the CRC as at least one of a TB level CRC or a CBG level CRC.

3. The UE of claim 1, wherein the CRC is a TB level CRC, and the TB level CRC is included in at least one of the CBG or a CB.

4. The UE of claim 3, wherein the TB level CRC is included at a beginning of a first CBG or a first CB of the TB.

5. The UE of claim 1, wherein the MCS level is a lowest MSC level of different MCS levels of the plurality of the MCSs associated with the transmission of the TB.

6. The UE of claim 1, wherein the MCS level is a first indicated value of a plurality of indicated MCS values.

7. The UE of claim 1, wherein the CRC is one or more CBG level CRCs, and the one or more CBG level CRCs are included in respective CBGs of the TB.

8. The UE of claim 7, wherein the one or more CBG level CRCs are associated with a different MCS level of the plurality of the MCSs.

9. A method performed by a user equipment (UE), the method comprising:
obtaining data for transmission, the data formable into a transport block (TB) of the data, the TB comprised of code block groups (CBGs), and each CBG comprises one or more code blocks (CBs) that each include a subset of the data, wherein a CBG of the CBGs is associated with a modulation and coding scheme (MCS) level of a plurality of MCSs; and
transmitting a cyclic redundancy check (CRC), wherein the CRC is calculated for the data or a subset of the data in the TB using the MCS level.

10. The method of claim 9, further comprising:
calculating the CRC as at least one of a TB level CRC or a CBG level CRC.

11. The method of claim 9, wherein the CRC is a TB level CRC, and the TB level CRC is included in at least one of the CBG or a CB.

12. The method of claim 11, wherein the TB level CRC is included at a beginning of a first CBG or a first CB of the TB.

13. The method of claim 9, wherein the MCS level is a lowest MSC level of different MCS levels of the plurality of the MCSs associated with the transmission of the TB.

14. The method of claim 9, wherein the MCS level is a first indicated value of a plurality of indicated MCS values.

15. The method of claim 9, wherein the CRC is one or more CBG level CRCs, and the one or more CBG level CRCs are included in respective CBGs of the TB.

16. The method of claim 15, wherein the one or more CBG level CRCs are associated with a different MCS level of the plurality of the MCSs.

17. An apparatus for wireless communication, comprising:
at least one memory; and
at least one processor coupled with the at least one memory and operable to cause the apparatus to:
form data into a transport block (TB) that is comprised of code block groups (CBGs), each CBG comprises one or more code blocks (CBs) that each include a subset of the data, wherein the CBGs are associated with modulation and coding scheme (MCS) levels of a plurality of MCSs; and
transmit a cyclic redundancy check (CRC), wherein the CRC is calculated for the data or a subset of the data in the TB using an MCS level associated with at least one of the CBGs or CBs.

18. The apparatus of claim 17, wherein the at least one processor is operable to cause the apparatus to calculate the CRC as at least one of a TB level CRC or a CBG level CRC.

19. The apparatus of claim 17, wherein the CRC is a TB level CRC, and the TB level CRC is included in at least one of the CBG or a CB.

20. A method performed by an apparatus, the method comprising:
forming data into a transport block (TB) that is comprised of code block groups (CBGs), each CBG comprises one or more code blocks (CBs) that each include a subset of the data, wherein the CBGs are associated with modulation and coding scheme (MCS) levels of a plurality of MCSs; and
transmitting a cyclic redundancy check (CRC), wherein the CRC is calculated for the data or a subset of the data in the TB using an MCS level associated with at least one of the CBGs or CBs.
